(19) United States
(12) Patent Application Publication
(10) Pub. No.: US 2026/0195495 A1
(43) Pub. Date: Jul. 9, 2026

(54) TRAINING SYSTEM, TRAINING METHOD, CONTROL SYSTEM, AND CONTROL METHOD

(71) Applicant: National Cheng Kung University, Tainan City (TW)

(72) Inventor: Yu-Hsien Lin, Tainan City (TW)

(73) Assignee: National Cheng Kung University, Tainan City (TW)

(21) Appl. No.: 19/443,371

(22) Filed: Jan. 8, 2026

Related U.S. Application Data
(60) Provisional application No. 63/742,874, filed on Jan. 8, 2025.

(51) Int. Cl. G06F 30/15; G05D 1/229; G05D 101/15; G05D 109/30

(52) U.S. Cl. CPC G06F 30/15; G05D 1/229; G05D 2101/15; G05D 2109/34

(57) ABSTRACT

A training system, a training method, a control system, and a control method, wherein the training method comprises the processing module performing the following steps: (a) initializing the training module; and (b) training the training module with a Twin Delayed Deep Deterministic (TD3) policy gradient algorithm based on a simulation unit.

### CROSS-REFERENCE TO RELATED APPLICATION

This application claims the benefit of U.S. provisional application Ser. No. 63/742,874 filed on Jan. 8, 2025, The entirety of the above-mentioned patent application is hereby incorporated by reference herein and made a part of the specification.

### BACKGROUND

### Technical Field

The present invention relates to the field of navigation control of unmanned surface vehicles, and in particular, to a technique applying a deep reinforcement learning technique to the navigation control of the unmanned surface vehicles.

### Related Art

Currently, conventional planning methods (such as A*, Dijkstra, and other algorithms) or PID control-based navigation methods are used in most of unmanned surface vehicle navigation control technical solutions. However, these methods perform well in static environments, but lack sufficient adaptability to sudden changes (such as drifting objects, ocean current shifts, and wind or wave disturbances).

### SUMMARY

In view of this, some embodiments of the present invention provide a training system, a training method, a control system, and a control method to address the problems in the prior art.

Some embodiments of the present invention provide a training system, including a simulation unit and a training unit, where the simulation unit is configured to, in response to receiving an action, return a reward corresponding to the action and a simulated next state of an unmanned surface vehicle, where the reward is the sum of a cross-track error reward value, a heading error reward value, a progress reward value, and a completion reward value, where the cross-track error reward value is used for giving a reward when an absolute value of a cross-track error is small and giving a penalty when the absolute value of the cross-track error increases, the heading error reward value is used for giving a reward when an absolute value of a heading error is small and giving a penalty when the absolute value of the heading error increases, the progress reward value is used for giving a reward when the unmanned surface vehicle advances in a mission direction and giving a penalty when the unmanned surface vehicle regresses or makes no progress, and the completion reward value is used for giving a reward when the unmanned surface vehicle approaches a waypoint and reaches a final destination; the training unit includes a training module and a processing module, where the training module includes an experience playback buffer, a first value network, a second value network, a policy network, a first target value network, a second target value network, and a target policy network, where the first target value network, the second target value network, and the target policy network are the same as the first value network, the second value network, and the policy network in architecture, respectively; and the processing module is configured to initialize the training module, and train the training module with a twin delayed deep deterministic policy gradient algorithm based on the simulation unit.

Some embodiments of the present invention provide a control system for a trained target policy network obtained by training using the aforementioned training system, where the control system includes a neural network module and a control processing module; the neural network module includes the trained target policy network; and the control processing module is configured to perform: receiving a current surge velocity, a current position, a current heading angle, a current cross-track error generated by an adaptive line-of-sight guidance law, and a current heading error of an unmanned surface vehicle as a current state of the unmanned surface vehicle, where the current heading error is a difference between an ideal heading angle generated by an adaptive line-of-sight guidance law and a current heading angle of the unmanned surface vehicle; inputting the current state into the trained target policy network to obtain an output; and controlling a propeller speed of the unmanned surface vehicle based on the aforementioned output.

Some embodiments of the present invention provide a training method, applicable to the aforementioned training system; and the training method includes: (a) initializing the training module; and (b) training the training module with a twin delayed deep deterministic policy gradient algorithm based on the simulation unit.

Some embodiments of the present invention provide a control method for a trained target policy network obtained by training using the aforementioned training method, where the control method is performed by the control processing module, and the control method includes: (a) receiving a current surge velocity, a current position, a current heading angle, a current cross-track error generated by an adaptive line-of-sight guidance law, and a current heading error of an unmanned surface vehicle as a current state of the unmanned surface vehicle, where the current heading error is a difference between an ideal heading angle generated by an adaptive line-of-sight guidance law and a current heading angle of the unmanned surface vehicle; (b) inputting the current state into the trained target policy network to obtain an output; and (c) controlling a propeller speed of the unmanned surface vehicle based on the output.

Based on the above, in the design of reward functions, related factors such as a cross-track error, a heading error, the progress of an unmanned surface vehicle in a mission direction, and the completion of a mission are comprehensively considered. The cross-track error reward value gives a reward when an absolute value of a cross-track error is small and gives a penalty when the absolute value increases to ensure close adherence to a preset path. The cross-track error reward value may increase path accuracy. The heading error reward value is used for giving a reward when an absolute value of a heading error is small and giving a penalty when the absolute value increases to ensure correct orientation. The heading error reward value may increase heading accuracy. The progress reward value gives a reward when the unmanned surface vehicle advances in a mission direction and gives a penalty when the unmanned surface vehicle regresses or makes no progress to avoid wandering. The progress reward value may restrain a behavior, and penalize a negative velocity to prevent regressing. The completion reward value gives a reward when the unmanned surface vehicle approaches a waypoint and gives a greater reward when the unmanned surface vehicle reaches a final destination, thereby encouraging the completion of a whole path. A target policy network (also called agent in the present invention) trained via a twin delayed deep deterministic policy gradient algorithm can be configured to control an unmanned surface vehicle and ensure that the unmanned surface vehicle can advance steadily and complete a mission while maintaining the path accuracy, thereby avoiding local optima (such as wandering in place or regressing). Moreover, through such multiple considerations, the reward function better approximate possible situations in real-world scenarios, thus improving the effectiveness and stability of a control policy. In addition, by using the twin delayed deep deterministic policy gradient algorithm, the overestimation problem can be reduced, so that the trained target policy network, when practically applied to control, has better performance than a controller trained by other algorithms (for example, a deep deterministic policy gradient (DDPG) algorithm).

### BRIEF DESCRIPTION OF THE DRAWINGS

FIG. 1 is a block diagram of a training system illustrated according to some embodiments of the present invention;

FIG. 2A is a schematic diagram of an unmanned surface vehicle illustrated according to some embodiments of the present invention;

FIG. 2B is a schematic diagram of path tracking of an unmanned surface vehicle illustrated according to some embodiments of the present invention;

FIG. 2C is a schematic diagram of a position increment illustrated according to some embodiments of the present invention;

FIG. 3 is a schematic diagram of a policy network illustrated according to some embodiments of the present invention;

FIG. 4 is a schematic diagram of a value network illustrated according to some embodiments of the present invention;

FIG. 5 is a schematic diagram of an experience playback buffer illustrated according to some embodiments of the present invention;

FIG. 6 is a schematic diagram of network relationships illustrated according to some embodiments of the present invention;

FIG. 7 is a schematic diagram of a normal distribution probability density function illustrated according to some embodiments of the present invention;

FIG. 8 is a schematic diagram of a clipped normal distribution probability density function illustrated according to some embodiments of the present invention;

FIG. 9 is a block diagram of a control system illustrated according to some embodiments of the present invention;

FIG. 10 is a block schematic diagram of an electronic device system illustrated according to some embodiments of the present invention;

FIG. 11 is a flowchart of a training method illustrated according to some embodiments of the present invention;

FIG. 12 is a flowchart of a training method illustrated according to some embodiments of the present invention;

FIG. 13 is a flowchart of a learning process illustrated according to some embodiments of the present invention;

FIG. 14 is a flowchart of a value network update process illustrated according to some embodiments of the present invention;

FIG. 15 is a flowchart of a policy network and target value network update process illustrated according to some embodiments of the present invention; and

FIG. 16 is a flowchart of a control method illustrated according to some embodiments of the present invention.

### DETAILED DESCRIPTION

The aforementioned and other technical contents, features, and effects of the present invention will be clearly presented in the detailed description of the embodiments in conjunction with the reference drawings below. Any modifications and changes that do not affect the efficacy and purpose of the present invention shall still fall within the scope of the technical content disclosed in the present invention. The same labels in all drawings will be used for representing the same or similar elements.

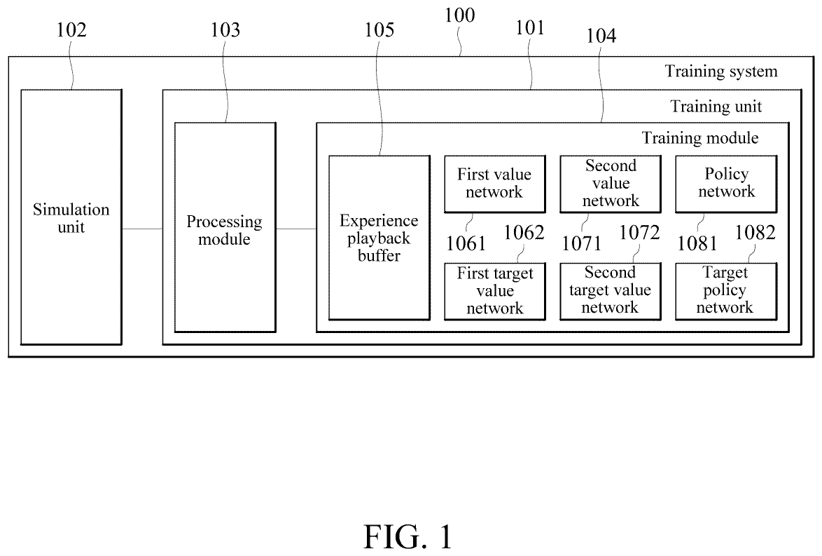

FIG. 1 is a block diagram of a training system illustrated according to some embodiments of the present invention. Referring to FIG. 1, a training system 100 includes a training unit 101 and a simulation unit 102.

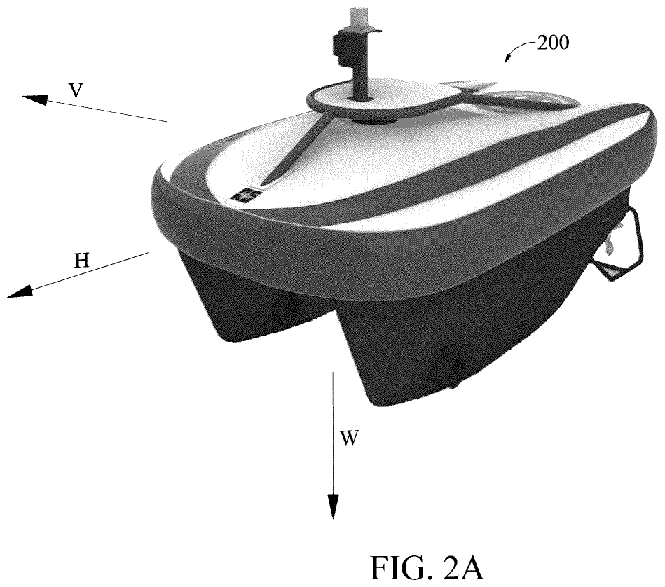

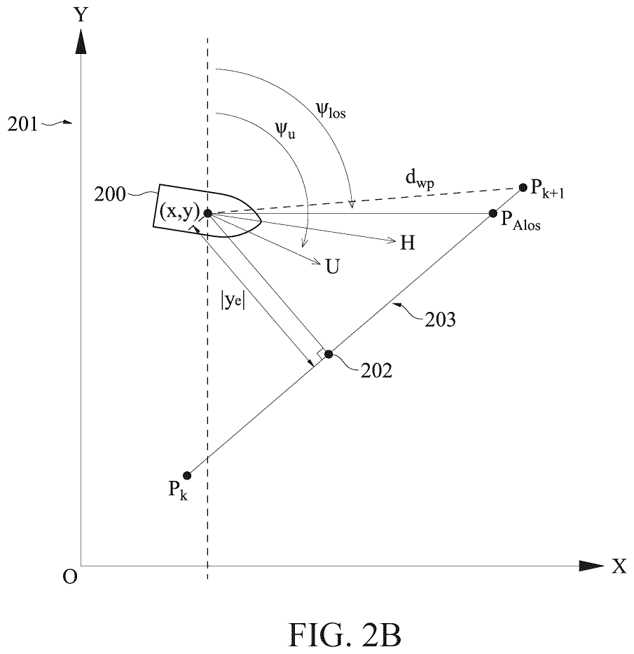

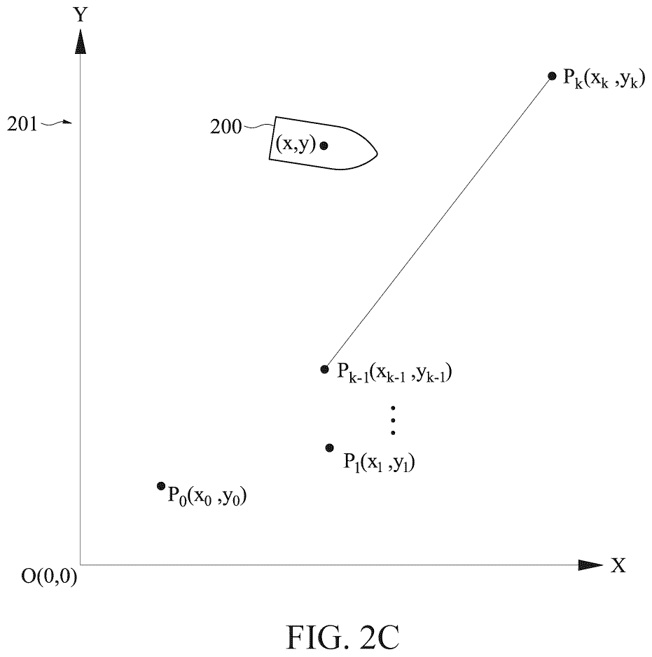

References are made to both FIG. 1 and FIG. 2A. The simulation unit 102 is configured to simulate an unmanned surface vehicle. The simulation unit 102 is configured to, in response to receiving an action, based on a current state of the unmanned surface vehicle simulated by the simulation unit 102 and the received action, return a reward corresponding to the action and a next state of the unmanned surface vehicle. Referring to FIG. 2A, in some embodiments of the present invention, the aforementioned unmanned surface vehicle is illustrated as an unmanned surface vehicle 200.

As illustrated in FIG. 2A, the unmanned surface vehicle 200 has a surge direction H, a sway direction V, and a heave direction W.

FIG. 2B is a schematic diagram of path tracking of an unmanned surface vehicle illustrated according to some embodiments of the present invention. References are made to both FIG. 2A and FIG. 2B. When the unmanned surface vehicle 200 performs path tracking on multiple waypoints Pᵢ based on an adaptive line-of-sight guidance law, a line segment between waypoints Pᵢ is a desired trajectory, where i=0, 1, 2, . . . , N, and N is a positive integer. As illustrated in FIG. 2B, waypoint Pₖ₊₁ is a current waypoint, and a line segment between waypoint Pₖ and the waypoint Pₖ₊₁ is a current desired trajectory 203, where k is a positive integer less than N. P_{N} is a final waypoint. A distance between the unmanned surface vehicle 200 and the current waypoint is distance d_{wp}.

In this embodiment, the unmanned surface vehicle 200 performs calculations using the adaptive line-of-sight guidance law based on a North-East coordinate system 201. Referring to FIG. 2B, the north-east coordinate system 201 has origin O, with the X-axis of the north-east coordinate system 201 pointing to geographic north, and the Y-axis of the North-East coordinate system 201 pointing to geographic east. Under the North-East coordinate system 201, a current position of the unmanned surface vehicle 200 is (x, y).

The deviation of the unmanned surface vehicle 200 relative to a current desired trajectory 203 is cross-track error yₑ of the unmanned surface vehicle 200 relative to the current desired trajectory 203. The cross-track error yₑ is also called a lateral tracking error. In this embodiment, when the unmanned surface vehicle 200 is on the left side of the current desired trajectory 203 (i.e., the left side when facing from the waypoint P_{K} to the waypoint P_{K+1}) (as illustrated in FIG. 2B, the unmanned surface vehicle 200 is on the left side of the current desired trajectory 203), the cross-track error yₑ is positive. When the unmanned surface vehicle 200 is on the right side of the current desired trajectory 203, the cross-track error yₑ is negative. An absolute value |yₑ| of the cross-track error yₑ is a projected distance between the unmanned surface vehicle 200 and the current desired trajectory 203. That is, the absolute value |yₑ| of the cross-track error yₑ is a distance between the unmanned surface vehicle 200 and a projection point 202 of the unmanned surface vehicle 200 on the current desired trajectory 203.

In this embodiment, a heading angle Ψᵤ of the unmanned surface vehicle 200 is defined as an included angle between the heading U and the geographic north direction. In order to track the current desired trajectory 203, the unmanned surface vehicle 200 generates an ideal heading angle Ψ_{Alos} based on the adaptive line-of-sight guidance law. As illustrated in FIG. 2B, the unmanned surface vehicle 200 points to a target point P_{ALOS} on the current desired trajectory 203 generated by the adaptive line-of-sight guidance law based on the ideal heading angle Ψ_{Alos}. It is worth noting that a surge direction H of the unmanned surface vehicle 200 is usually different from the heading U.

In some embodiments of the present invention, the state of the unmanned surface vehicle 200 includes a surge velocity u in the surge direction H and a sway velocity v in the sway direction V of the unmanned surface vehicle 200, a position (x, y) of the unmanned surface vehicle 200, a heading angle Ψᵤ of the unmanned surface vehicle 200, a cross-track error yₑ of the unmanned surface vehicle 200, and a heading error Ψₑᵣᵣ of the unmanned surface vehicle 200. The heading error Ψₑᵣᵣ is defined as a difference Ψₗₒₛ−Ψᵤ between an ideal heading angle Ψₗₒₛ generated by the adaptive line-of-sight guidance law and the heading angle Ψᵤ. A control input of the unmanned surface vehicle 200 is a propeller speed of the unmanned surface vehicle 200. In this embodiment, the state of the unmanned surface vehicle 200 may be represented by a seven-dimensional vector s=[u,v,x,y,Ψᵤ,yₑ,Ψₑᵣᵣ]. The simulation unit 102 is configured to, in response to receiving an action a transmitted by the training unit 101 as the control input of the unmanned surface vehicle 200. The simulation unit 102 returns a next state sₙₑₓₜ=[uₙₑₓₜ,vₙₑₓₜ,xₙₑₓₜ,yₙₑₓₜ,Ψ_{u,next}, y_{e,next},Ψ_{err,next}] of the unmanned surface vehicle 200 simulated by the simulation unit 102 and a reward r based on a current state s_{current} [u_{current},v_{current},x_{current},y_{current},Ψ_{u,current}, y_{e,current},Ψ_{err,current}] and the received action a.

In some embodiments of the present invention, the simulation unit 102 uses an otter model in a marine systems simulator (MSS) of MATLAB to simulate an unmanned surface vehicle 200 in order to generate a next state sₙₑₓₜ=[uₙₑₓₜ,vₙₑₓₜ,xₙₑₓₜ,yₙₑₓₜ,Ψ_{u,next}, y_{e,next},Ψ_{err,next}] of the unmanned surface vehicle 200 based on a current state s_{current} [u_{current},v_{current},x_{current},y_{current},Ψ_{u,current}, y_{e,current},Ψ_{err,current}] and a received action a. By setting parameters of the otter model, the otter model may be used to simulate the unmanned surface vehicle 200. The marine systems simulator is an MATLAB/Simulink open-source Simulink Toolbox specifically designed for maritime systems. The open-source Simulink Toolbox integrates kinematic and dynamic models of ships, underwater vehicles, and offshore floating platforms, and comes with a complete built-in guidance, navigation, and control (GNC) module. The Simulink Toolbox provides various Simulink modules, such as physical models, controllers, autonomous driving, dynamic positioning (DP), navigation filters, and actuators, which can help researchers quickly build simulation systems for ship maneuvering, underwater vehicle navigation, and floating platform dynamic responses. The model of the marine systems simulator is comprehensive and closely emulates real physical behaviors. Users can freely modify and extend all MATLAB/Simulink files. The marine systems simulator has a high degree of visualization, complete functions, and open-source friendliness. The marine systems simulator is an extremely commonly used tool in the development of maritime control and navigation systems, widely applicable to ship control, underwater vehicle path tracking, dynamic positioning system design, and various ocean engineering simulation requirements, and can be extended as needed.

It is worth noting that in the aforementioned embodiment, an otter model is used to simulate the unmanned surface vehicle 200. However, as long as the parameters of the otter model are obtained via experiments, the otter model may be used to simulate any catamaran hull. The present invention is not limited to the unmanned surface vehicle 200 illustrated in FIG. 2.

In addition, it is worth noting that the otter model in the marine systems simulator (MSS) of MATLAB is used to simulate the unmanned surface vehicle 200 in the aforementioned embodiment. However, other types of simulation software (for example HoloOcean) simulate the unmanned surface vehicle 200. The present invention is not limited to the marine systems simulator of MATLAB.

In some embodiments of the present invention, the aforementioned reward r is the sum of a cross-track error reward value r_{ye}, a heading error reward value r_{head}, a progress reward value r_{prog}, and a completion reward value r_{comp}. The cross-track error reward value r_{ye} is used for giving a reward when an absolute value |yₑ| of a cross-track error yₑ is small and giving a penalty when the absolute value |yₑ| increases to ensure close adherence to a preset path. The heading error reward value r_{head} is used for giving a reward when an absolute value |Ψₑᵣᵣ| of a heading error Ψₑᵣᵣ is small and giving a penalty when the absolute value |Ψₑᵣᵣ| increases to ensure correct orientation. The progress reward value r_{prog} gives a reward when the unmanned surface vehicle 200 advances in a mission direction and gives a penalty when the unmanned surface vehicle regresses or makes no progress to avoid wandering. The completion reward value r_{comp} gives a reward when the unmanned surface vehicle 200 approaches a waypoint (for example, the aforementioned waypoint Pᵢ, where i=0, 1, 2, . . . , N) and gives a greater reward when the unmanned surface vehicle reaches a final destination, thereby encouraging the completion of a whole path.

Referring to FIG. 1 again, in some embodiments of the present invention, the training unit 101 includes a processing module 103 and a training module 104. The training module 104 includes an experience playback buffer 105, a first value network 1061, a second value network 1071, a policy network 1081, a first target value network 1062, a second target value network 1072 and a target policy network 1082. The first value network 1061, the second value network 1071, the policy network 1081, the first target value network 1062, the second target value network 1072, and the target policy network 1082 are each a neural network, and the first target value network 1062, the second target value network 1072, and the target policy network 1082 are each the same as the first value network 1061, the second value network 1071, and the policy network 1081 in architecture.

In the present invention, a parameter of the first value network 1061 is denoted as θ₁, a parameter of the second value network 1071 is denoted as θ₂, a parameter of the policy network 1081 is denoted as (p, a parameter of the first target value network 1062 is denoted as [symbol] , a parameter of the second target value network 1072 is denoted as [symbol] , and a parameter of the target policy network 1082 is denoted as Pp.

The experience playback buffer 105 is configured to, when the training unit 101 and the simulation unit 102 interoperate, store a current state of the simulation unit 102, an action transmitted by the training unit 101, as well as a reward returned by the simulation unit 102 in response to receiving the action, based on a current state of the unmanned surface vehicle and the received action, and a next state of the unmanned surface vehicle. The experience playback buffer 105 may be implemented by a memory.

The processing module 103 is configured to generate the aforementioned action based on the training module 104.

The training method of some embodiments of the present invention and how various modules of the training system 100 cooperate with each other will be described below in details with the figures.

FIG. 11 is a flowchart of a training method illustrated according to some embodiments of the present invention. Referring to both FIG. 1 and FIG. 11, in an embodiment illustrated in FIG. 11, the training method is performed by the processing module 103, and is used for training the training module 104. The training method includes performing steps S1101 to S1102 by the processing module 103. In step S1101, the processing module 103 initializes the training module 104. In step S1102, the processing module 103 trains the training module 104 with a twin delayed deep deterministic (TD3) policy gradient algorithm based on the simulation unit 102. The twin delayed deep deterministic policy gradient algorithm is also called a TD3 algorithm.

In the aforementioned embodiment, in the design of reward functions, related factors such as a cross-track error, a heading error, progress, and completion are comprehensively considered. The cross-track error reward value r_{ye} gives a reward when an absolute value |yₑ| of a cross-track error yₑ is small and gives a penalty when the absolute value |yₑ| increases to ensure close adherence to a preset path. The cross-track error reward value r_{ye} may increase path accuracy. The heading error reward value r_{head} is used for giving a reward when an absolute value |Ψₑᵣᵣ| of a heading error Ψₑᵣᵣ is small and giving a penalty when the absolute value |Ψₑᵣᵣ| increases to ensure correct orientation. The heading error reward value r_{head} may increase heading accuracy. The progress reward value r_{prog} gives a reward when the unmanned surface vehicle 200 advances in a mission direction and gives a penalty when the unmanned surface vehicle regresses or makes no progress to avoid wandering. The progress reward value r_{prog} may restrain a behavior, and penalize a negative velocity to prevent regressing. The completion reward value r_{comp} gives a reward when the unmanned surface vehicle 200 approaches a waypoint (for example, the aforementioned waypoint Pᵢ, where i=0, 1, 2, . . . , N) and gives a greater reward when the unmanned surface vehicle reaches a final destination, thereby encouraging the completion of a whole path. In the overall design of reward functions, a hierarchical reward structure is employed to balance all objectives, thereby ensuring that an agent advances steadily and completes a mission while maintaining the path accuracy, and thus avoiding local optima (such as wandering in place or regressing).

In some embodiments of the present invention, the policy network 1081 is a first fully connected network, the first value network 1061 is a second fully connected network, and the second value network 1071 is a third fully connected network. An activation function of an output layer of the first fully connected network is a hyperbolic tangent function, an activation function of an output layer of the second fully connected network is a linear function, and an activation function of an output layer of the third fully connected network is a linear function.

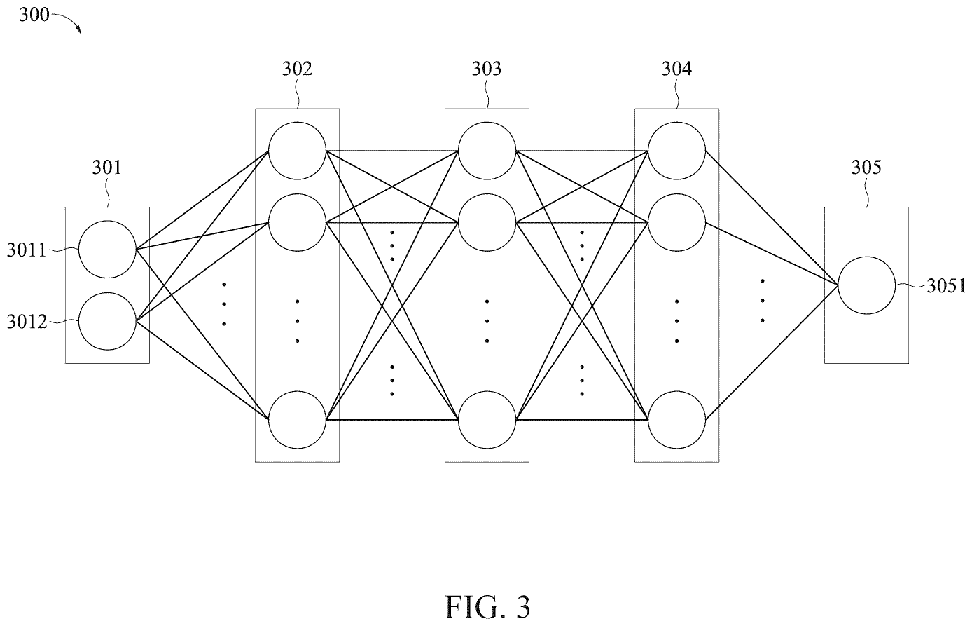

FIG. 3 is a schematic diagram of a policy network illustrated according to some embodiments of the present invention. Referring to FIG. 3, in some embodiments of the present invention, the policy network 1081 is a first fully connected network 300. The first fully connected network 300 includes an input layer 301, intermediate layers 302 to 304, and an output layer 305. In this embodiment, a state of the unmanned surface vehicle 200 includes two elements (for example, the state of the aforementioned unmanned surface vehicle 200 includes a roll angle φ and the surge velocity u), and the input layer 301 includes input neurons 3011 to 3012 for receiving the state of the unmanned surface vehicle 200. The output layer 305 includes an output neuron 3051. The activation function of the output neuron 3051 of the output layer 305 is a hyperbolic tangent function. The parameter φ of the policy network 1081 includes all weights and biases of the first fully connected network 300.

In an embodiment of FIG. 3, since the architecture of the target policy network 1082 is the same as the architecture of the policy network 1081, the target policy network 1082 is a fully connected network which is the same as the first fully connected network 300 in architecture. The parameter \hat{φ} of the target policy network 1082 includes all the weights and biases of the first fully connected network that are included in the target policy network 1082.

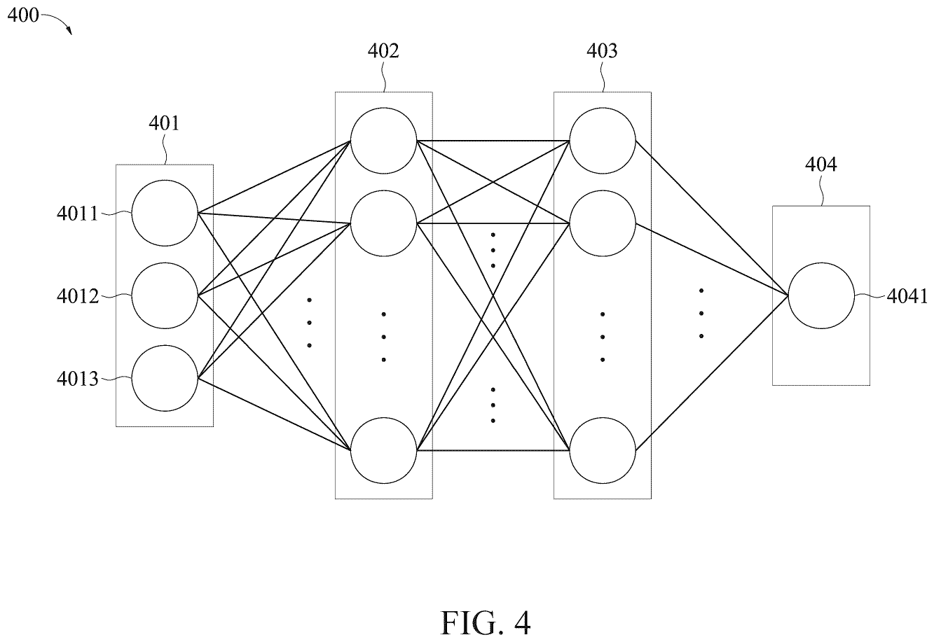

FIG. 4 is a schematic diagram of a value network illustrated according to some embodiments of the present invention. Referring to FIG. 4, in some embodiments of the present invention, the first value network 1061 is a second fully connected network, and the second value network 1071 is a third fully connected network. In this embodiment, the second fully connected network and the third fully connected network are the same as the fully connected network 400 in architecture. The fully connected network 400 includes an input layer 401, intermediate layers 402 to 403, and an output layer 404. In this embodiment, a state of the unmanned surface vehicle 200 includes two elements (for example, the state of the aforementioned unmanned surface vehicle 200 includes a roll angle Y and the surge velocity u), and the input layer 401 includes input neurons 4011 to 4012 for receiving the state of the unmanned surface vehicle 200. The output layer 404 includes an output neuron 4041. The activation function of the output neuron 4041 of the output layer 404 is a linear function. The parameter θ₁ of the aforementioned first value network 1061 includes all weights and biases of the second fully connected network. The parameter θ₂ of the aforementioned second value network 1071 includes all the weights and biases of the second fully connected network. The input neuron 4013 is configured to receive an exploration action. The exploration action is the output of the policy network 1081 corresponding to the current state plus exploration noise. The actions of the first value network 1061, the second value network 1071, the policy network 1081, the first target value network 1062, the second target value network 1072, and the target policy network 1082 will be further explained in the embodiments described later.

In an embodiment of FIG. 4, since the first target value network 1062 and the second target value network 1072 are each the same as the first value network 1061 and the second value network 1071 in architecture, the architectures of the first target value network 1062 and the second target value network 1072 are all the same as that of the fully connected network 400. The parameter [symbol] of the first target value network 1062 includes all weights and biases of the first target value network 1062. The parameter [symbol] of the second target value network 1072 includes all the weights and biases of the second target value network 1072.

In this embodiment, the aforementioned step S1101 includes initializing respective weights and biases of the first value network 1061, the second value network 1071, the policy network 1081, the first target value network 1062, the second target value network 1072, and the target policy network 1082. In some embodiments of the present invention, the processing module 103 initializes respective weights and biases of the first value network 1061, the second value network 1071, the policy network 1081, the first target value network 1062, the second target value network 1072, and the target policy network 1082 based on a normal distribution.

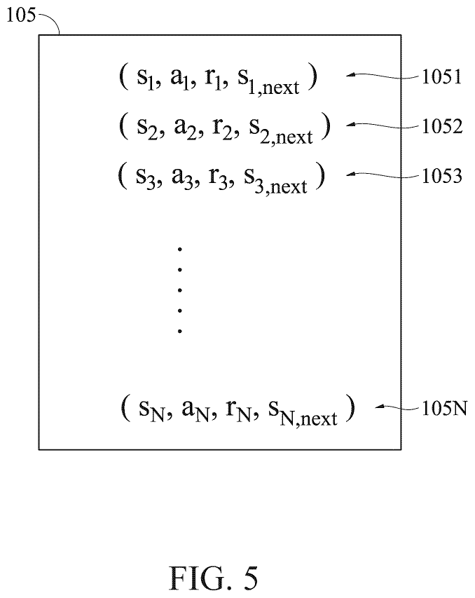

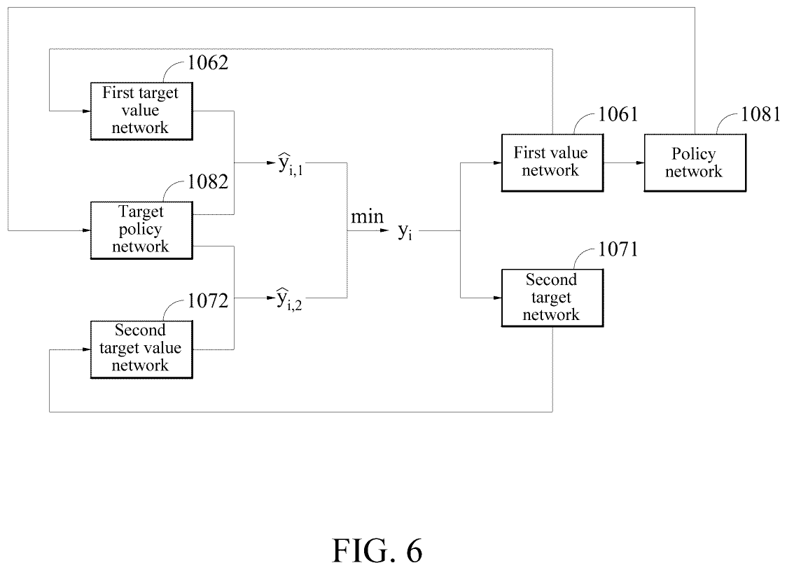

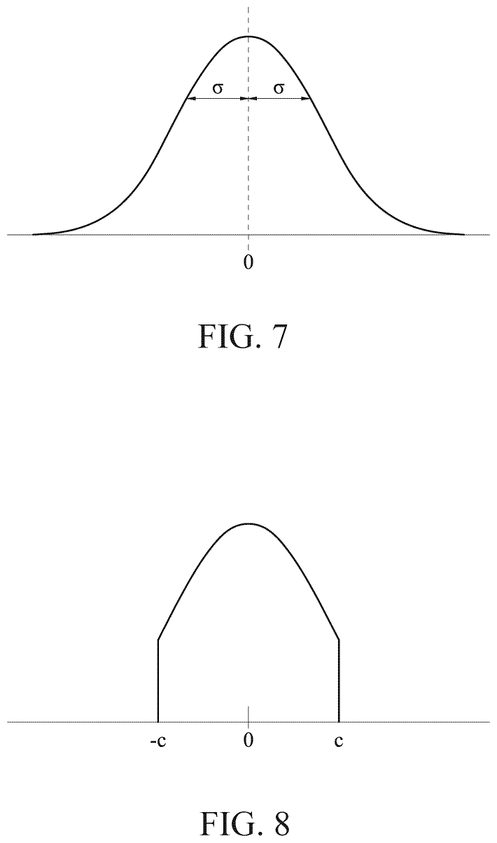

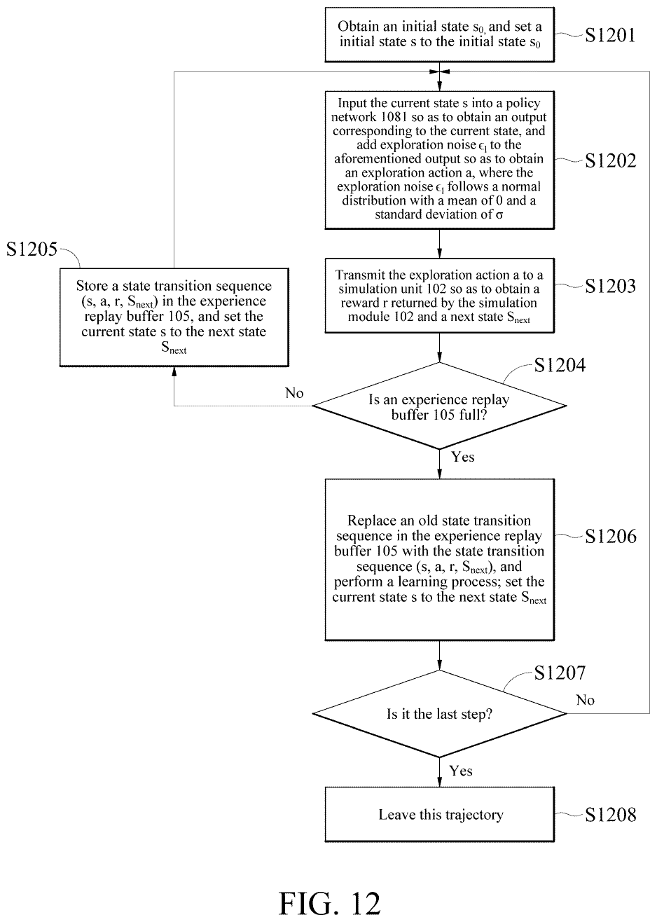

FIG. 5 is a schematic diagram of an experience playback buffer illustrated according to some embodiments of the present invention. FIG. 6 is a schematic diagram of network relationships illustrated according to some embodiments of the present invention. FIG. 7 is a schematic diagram of a normal distribution probability density function illustrated according to some embodiments of the present invention. FIG. 12 is a flowchart of a training method illustrated according to some embodiments of the present invention. Also referring to FIG. 1, FIG. 2, FIG. 5, FIG. 6, FIG. 11, and FIG. 12, in an embodiment illustrated in FIG. 12, the aforementioned step S1102 includes performing steps S1201 to S1208 on each of a plurality of trajectories. In step S1201, an initial state s₀ of an unmanned surface vehicle (for example, the unmanned surface vehicle 200) simulated by the simulation unit 102 is obtained, and a current state s is set to the initial state so.

Hereafter, a function relationship applied by the policy network 1081 in a case where a parameter of the policy network 1081 is θ is represented by π_{θ}( ). In step S1202, the processing module 103 inputs the current state s into the policy network 1081 to obtain an output π_{θ}(s) corresponding to the current state s. Next, the processing module 103 adds exploration noise ϵ₁ to the aforementioned output π_{θ}(s) so as to obtain an exploration action a=π_{θ}(s)+ϵ₁. The exploration noise ϵ₁ follows a normal distribution with a mean of 0 and a standard deviation of σ. FIG. 7 illustrates a probability density function of a normal distribution with a mean of 0 and a standard deviation of σ.

In step S1203, the processing module 103 transmits the exploration action a to the simulation unit 102 so as to obtain a reward r returned by the simulation unit 102 and a next state sₙₑₓₜ of the unmanned surface vehicle simulated by the simulation unit 102. In step S1204, the processing module 103 determines whether the experience playback buffer 105 is full. If yes, step S1206 is performed, and if no, step S1205 is performed.

In step S1205, the processing module 103 stores a state transition sequence (s, a, r, sₙₑₓₜ) consisting of the current state s, the exploration action a, the reward r, and the next state sₙₑₓₜ in the experience playback buffer 105. Referring to FIG. 5, as shown in FIG. 5, the processing module 103, before the experience playback buffer 105 is full, sequentially stores the state transition sequences 1051 to 105N in the experience playback buffer 105, where N is a positive integer, and a current state s₁ of the state transition sequence 1051 is an initial state so. In this embodiment, when N does not reach the preset storage capacity of the experience playback buffer 105, the processing module 103 determines that the experience playback buffer 105 is not full, and when N reaches the preset storage capacity of the experience playback buffer 105, the processing module 103 determines that the experience playback buffer 105 is full. After the state transition sequence (s, a, r, sₙₑₓₜ) consisting of the current state s, the exploration action a, the reward r, and the next state sₙₑₓₜ is stored in the experience playback buffer 105, the current state s is set to the next state sₙₑₓₜ and step S1202 is returned.

In step S1206, in response to the experience playback buffer 105 being full, the processing module 103 replaces an old state transition sequence in the experience playback buffer 105 with the state transition sequence (s, a, r, sₙₑₓₜ), and performs a learning process. After the learning process is performed, the current state s is set to the next state sₙₑₓₜ. It is worth noting that after the experience playback buffer 105 is full, the processing module 103 may replace an old state transition sequence with a new state transition sequence in order of a state transition sequence 1051, a state transition sequence 1052, etc.

In step S1207, the processing module 103 determines whether step S1207 is the last step of this trajectory. If yes, step S1208 is entered, and if no, step S1202 is returned. In step S1208, the processing module 103 leaves this trajectory.

It is worth noting that the processing module 103, when steps S1201 to S1208 are performed, may continuously accumulate a count variable so as to count the number of repetitions of steps S1201 to S1208. In step S1207, when the processing module 103 determines whether the numerical value of the count variable reaches a preset number of steps, if yes, the processing module 103 determines that step S1207 is the last step of this trajectory.

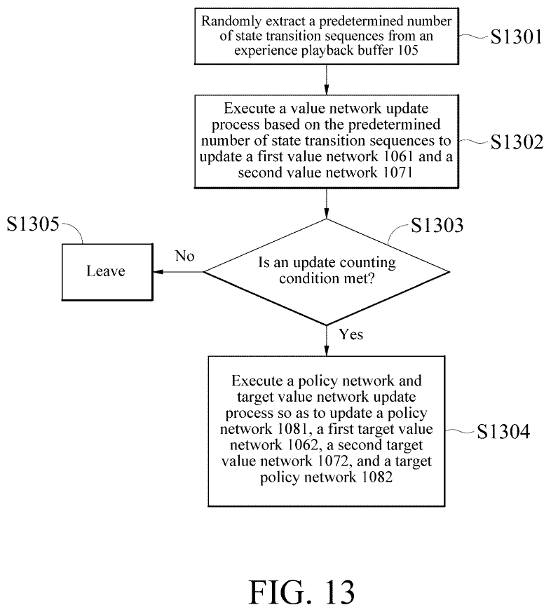

FIG. 13 is a flowchart of a learning process illustrated according to some embodiments of the present invention. Referring to FIG. 13, in an embodiment illustrated in FIG. 13, the learning process includes steps S1301 to S1305. In step S1301, the processing module 103 randomly extracts a predetermined number of state transition sequences from the experience playback buffer 105. The aforementioned predetermined number is M, where M is a positive integer. In step S1302, the processing module 103 executes a value network update process based on the predetermined number of state transition sequences to update the first value network 1061 and the second value network 1071. In step S1303, the processing module 103 determines whether an update counting condition is met. if yes, step S1304 is performed, and if no, step S1305 is performed so as to leave this learning process.

In step S1304, the processing module 103 executes a policy network and target value network update process so as to update the policy network 1081, the first target value network 1062, the second target value network 1072, and the target policy network 1082.

It is worth noting that in the aforementioned steps S1303 to S1304, only when the update counting condition is met, the processing module 103 proceeds to step S1304 to update the policy network 1081, the first target value network 1062, the second target value network 1072, and the target policy network 1082. This allows update frequencies of the policy network 1081, the first target value network 1062, the second target value network 1072, and the target policy network 1082 to be lower than those of the first value network 1061 and the second value network 1071. The update frequencies of the policy network 1081, the first target value network 1062, the second target value network 1072, and the target policy network 1082 are lower than those of the first value network 1061 and the second value network 1071, such that better update quality of the policy network 1081 and the target policy network 1082 can be obtained.

In some embodiments of the present invention, the update counting condition is whether the aforementioned counting variable is a multiple of a positive integer m. Such an update counting condition may allow the policy network 1081, the first target value network 1062, the second target value network 1072, and the target policy network 1082 to be updated only after the first value network 1061 and the second value network 1071 have been updated m times.

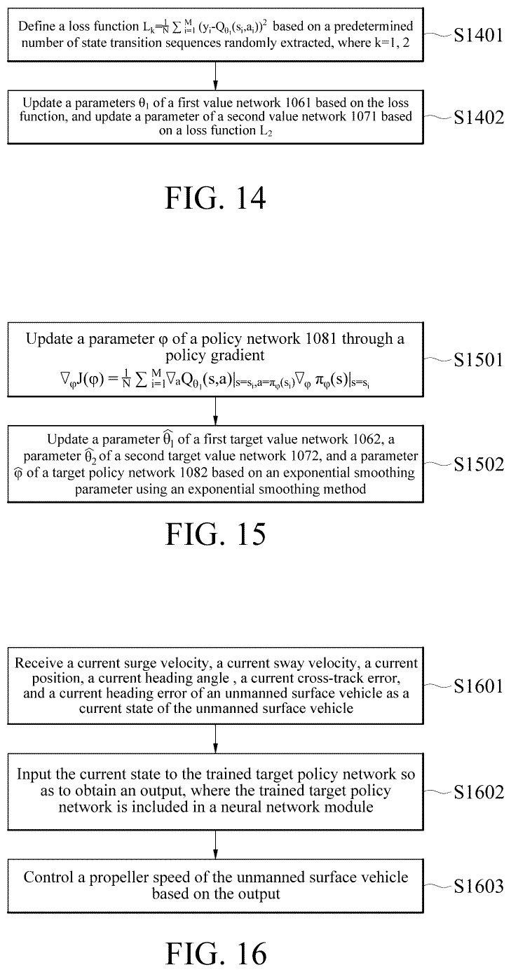

FIG. 8 is a schematic diagram of a clipped normal distribution probability density function illustrated according to some embodiments of the present invention. FIG. 14 is a flowchart of a value network update process illustrated according to some embodiments of the present invention. Referring to FIG. 14, continuing from an embodiment illustrated in FIG. 13, the value network update process includes steps S1401 to S1402. For the convenience of explanation, the predetermined number of state transition sequences randomly extracted from the experience playback buffer 105 by the processing module 103 in the aforementioned step S1301 are denoted as (sᵢ, aᵢ, rᵢ, s_{i, next}), where i=1, 2, . . . , M. For the convenience of explanation, in the following, a function relationship applied by the first value network 1061 in a case where a parameter of the first value network 1061 is θ₁ is represented by Q_{θ}_{₁}( ); a function relationship applied by the second value network 1071 in a case where a parameter of the second value network 1071 is θ₂ is represented by Q_{θ}_{₂}( ); a function relationship applied by the first target value network 1062 in a case where a parameter of the first target value network 1062 is [symbol] is represented by [symbol] ( ); a function relationship applied by the second target value network 1072 in a case where a parameter of the second target value network 1072 is [symbol] is represented by [symbol] ( ); and a function relationship applied by the target policy network 1082 in a case where a parameter of the target policy network 1082 is \hat{φ} is represented by π_{\hat{φ}}( ).

In step S1401, the processing module 103 defines a loss function

$${L}_{k} = \frac{1}{M} {\sum }_{i = 1}^{M} {( {y}_{i} - {Q}_{{θ}_{k}} ( {s}_{i} , {a}_{i} ) )}^{2}$$

based on a predetermined number of state transition sequences randomly extracted, where k=1, 2. yᵢ is obtained via the following steps. In a first step, for all i∈{1, 2 . . . M}, a next state s_{i, next} is inputted into the target policy network 1082 so as to obtain an output π_{\hat{φ}}(s_{i, next}) corresponding to the next state s_{i, next}. Next, the processing module 103 adds exploration noise ϵ₂ to the aforementioned output π_{\hat{φ}} (s_{i, next}) so as to obtain an exploration action ã_{i,next}=π_{\hat{φ}}(s_{i,next})+ϵ₂. The exploration noise ϵ₂ follows a clipped normal distribution with a mean of 0, a standard deviation of σ, and a clipped value of c. As illustrated in FIG. 8, the clipped normal distribution with a mean of 0, a standard deviation of σ, and a clipped value of c is a normal distribution with a mean of 0 and a standard deviation of σ, but the probability of a variable falling outside interval [−c, c] is 0. In a second step, for all i∈{1, 2 . . . M}yᵢ=rᵢ+min_{k=1,2} [symbol] (s_{i, next},ã_{i,next}) is calculated, where min_{k=1,2} [symbol] (s_{i,next},ã_{i,next}) represents that a smaller one is taken from ŷ_{i,1}= [symbol] (s_{i, next},ã_{i,next}) and ŷ_{i,2}= [symbol] (s_{i, next},ã_{i,next}). The aforementioned yᵢ is also called a TD target.

In step S1402, the processing module 103 updates a parameter θ₁ of the first value network 1061 based on a loss function L₁ and updates a parameter θ₂ of the second value network 1071 based on a loss function L₂. In this step, since the loss function L₁ and the loss function L₂ are defined, the parameter θ₁ of the first value network 1061 may be updated based on the loss function L₁, and the parameter θ₂ of the second value network 1071 may be updated based on the loss function L₂ and based on a back-propagation algorithm and an Adam method.

FIG. 15 is a flowchart of a policy network and target value network update process illustrated according to some embodiments of the present invention. Referring to FIG. 15, continuing from an embodiment illustrated in FIG. 13 and FIG. 14, the policy network and target value network update process includes steps S1501 to S1502. In step S1501, the processing module 103 updates a parameter φ of the policy network 1081 through a policy gradient

$${{{∇}_{φ} J ( φ ) = \frac{1}{M} {\sum }_{i = 1}^{M} {∇}_{a} {Q}_{{θ}_{1}} ( s , a ) \vert}_{s = {s}_{i} , a = {π}_{φ} ( {s}_{i} )} {∇}_{φ} {π}_{φ} ( s ) \vert}_{s = {s}_{i}} .$$

In step S1502, the processing module 103 updates a parameter [symbol] of the first target value network 1062, a parameter [symbol] of the second target value network 1072, and a parameter \hat{φ} of the target policy network 1082 based on an exponential smoothing parameter ρ using an exponential smoothing method. In this embodiment, the processing module 103 updates the parameter [symbol] of the first target value network 1062 with ρθ₁+(1−ρ) [symbol] , the processing module 103 updates the parameter [symbol] of the second target value network 1072 with ρθ₂+(1−ρ) [symbol] and the processing module 103 updates the parameter of the target policy network 1082 with ρφ+(1−ρ)\hat{φ}.

Referring to both FIG. 1 and FIG. 2 again, in some embodiments of the present invention, the simulation unit 102 generates a cross-track error reward value r_{ye} based on the following steps: (a) in response to an absolute value |yₑ| of a cross-track error yₑ being less than or equal to a first predetermined value y₁, setting the cross-track error reward value r_{ye} to a difference between the first predetermined value y₁ and the absolute value |yₑ| of the cross-track error yₑ multiplied by a first numerical value, where the first numerical value a₁ is a positive real number; (b) in response to the absolute value |yₑ| of the cross-track error yₑ being greater than the first predetermined value y₁ and less than or equal to a second predetermined value y₂, setting the cross-track error reward value r_{ye} as the difference between the absolute value |yₑ|, of the cross-track error yₑ and the first predetermined value y₁ multiplied by a second numerical value a₂, where the second numerical value a₂ is a negative real number; and (c) in response to the absolute value |yₑ| of the cross-track error yₑ being greater than the second predetermined value y₂, setting the cross-track error reward value r_{ye} to a third numerical value a₃, where the third numerical value a₃ is a negative real number. The cross-track error reward value r_{ye} may be expressed by the following equation:

$${r}_{roll} = \{ \begin{matrix}{a}_{1} \cdot ( {y}_{1} - \vert {y}_{e} \vert ) , if \vert {y}_{e} \vert \leq {y}_{1} , \\ - \vert {a}_{1} \vert \cdot ( \vert {y}_{e} \vert - {y}_{1} ) , if {y}_{1} \leq \vert {y}_{e} \vert \leq {y}_{2} , \\ - \vert {a}_{3} \vert , if \vert {y}_{e} \vert \leq {y}_{2}\end{matrix} .$$

In some embodiments of the present invention,

$${a}_{1} = 100 , {a}_{2} = \frac{- 100}{7} , {a}_{3} = - 25 , {y}_{1} = 0.3 , and {y}_{2} = 1. .$$

In some embodiments of the present invention, the simulation unit 102 generates a heading error reward value r_{head} based on the following steps: (a) in response to an absolute value |Ψₑᵣᵣ| of a heading error Ψₑᵣᵣ being less than or equal to a preset angle γ, calculating the ratio of the absolute value |Ψₑᵣᵣ| of the heading error |Ψₑᵣᵣ| to the preset angle γ, and setting the heading error reward value r_{head} to a difference

$$( 1 - \frac{\vert {Ψ}_{e r r} \vert}{γ} )$$

between 1 and the ratio

$$\frac{\vert {Ψ}_{e r r} \vert}{γ}$$

multiplied by a fourth numerical value a₄, where the preset angle γ is a positive angle and the fourth numerical value a₄ is a positive real number; and (b) in response to the absolute value |Ψₑᵣᵣ| of the heading error Ψₑᵣᵣ being greater than the preset angle γ, setting the heading error reward value r_{head} to a fifth numerical value a₅ multiplied by the absolute value |Ψₑᵣᵣ| of the heading error Ψₑᵣᵣ, where the fifth numerical value is a negative real number. The heading error reward value r_{head} may be expressed by the following equation:

$${r}_{head} = \{ \begin{matrix}{a}_{4} \cdot ( 1 - \frac{\vert {Ψ}_{e r r} \vert}{γ} ) , if \vert {Ψ}_{\cdot err} \vert \leq γ , \\ - \vert {a}_{5} \vert \cdot \vert {Ψ}_{e r r} \vert , if \vert {Ψ}_{e r r} \vert > γ\end{matrix} .$$

In some embodiments of the present invention,

$${a}_{4} = 15 , and {a}_{5} = \frac{- 5}{π} .$$

FIG. 2C is a schematic diagram of a position increment illustrated according to some embodiments of the present invention. Referring to FIG. 2C, continuing from an embodiment of FIG. 2B, the unmanned surface vehicle 200 performs path tracking on multiple waypoints Pᵢ based on an adaptive line-of-sight guidance law, where i=0, 1, 2, . . . , N, waypoint Pₖ is a current waypoint, and a position of the unmanned surface vehicle 200 at time t is (x(t), y(t)). The coordinates of origin O are (0, 0), and the coordinates of the waypoint Pᵢ are (xᵢ, yᵢ), where i=0, 1, 2, . . . , N. For the convenience of explanation,

$${L}_{0} = \sqrt{{x}_{0}^{2} + {y}_{0}^{2}}$$

(i.e. a distance from the waypoint P₀ to the origin O) and Lᵢ=\sqrt{(xᵢ−xᵢ₋₁)²+(yᵢ−yᵢ₋₁)²} (i.e. a distance from the waypoint Pᵢ to waypoint Pᵢ₋₁) are defined, where i=0, 1, 2, . . . , N. Let track(t) represent the number of a current waypoint of the unmanned surface vehicle 200 at time t. By way of example, if the current waypoint of the unmanned surface vehicle 200 at time t_{current} is Pₖ, then track(t_{current})=k. Let a current waypoint distance d_{target}(t)={square root over ((x_{track(t)}−x₍ₜ₎)²−(y_{track(t)}−y(t))²)} (i.e., a distance from the position of the unmanned surface vehicle 200 at time t to the current waypoint). Let a current travel path length total

$$( t ) = ( {\sum }_{i = 0}^{t r a c k ( t ) - 1} {L}_{i} ) + max ( 0 , {L}_{t r a c k ( t )} - {d}_{target} ( t ) ) ,$$

where max(0,L_{track(t)}−d_{target}(t) represents that a larger one is taken from 0 and L_{track(t)}−d_{target}(t). In this embodiment, at two adjacent time steps s₁ and s₂ during simulation, a time-step movement increment ΔP of the unmanned surface vehicle 200 on a desired trajectory is defined as total(s₂)−total(s₁), where s₂>s₁.

The simulation unit 102 generates a progress reward value r_{prog} based on the following steps: (a) in response to a time-step movement increment ΔP being greater than a first variation amount DP1, setting the progress reward value r_{prog} to a sixth numerical value a₆ multiplied by the time-step movement increment ΔP, where the first variation amount DP1 is a positive real number and the sixth numerical value a₆ is a positive real number; (b) in response to the time-step movement increment ΔP being less than a second variation amount DP2, setting the progress reward value r_{prog} to a seventh numerical value a₇, where the second variation amount DP2 is a negative real number, and the seventh numerical value a₇ is a negative real number; and (c) in response to the time-step movement increment ΔP being greater than or equal to the second variation amount DP2 and less than or equal to the first variation amount DP1, setting the progress reward value r_{prog} to an eighth numerical value a₈, where the eighth numerical value as is a negative real number. The progress reward value r_{prog} may be expressed by the following equation:

$${r}_{p r o g} = \{ \begin{matrix}{a}_{6} \cdot Δ P , if Δ P > DP 1 , \\ - \vert {a}_{7} \vert , if Δ P < DP 2 , \\ - \vert {a}_{8} \vert , if DP 2 \leq Δ P \leq DP 1\end{matrix} .$$

In some embodiments of the present invention, DP1=0.1, DP2=−0.1, a₆=30, a₇=−20, and a₆=−30.

Referring to FIG. 2B again, in some embodiments of the present invention, the simulation unit 102 generates a completion reward value r_{comp} based on the following steps: (a) in response to a current waypoint (for example, waypoint Pₖ₊₁) being a final waypoint and a distance d_{wp} between the unmanned surface vehicle 200 and the current waypoint being less than or equal to a first distance d₁, setting the completion reward value r_{comp} to a ninth numerical value a₉, where the ninth numerical value a₉ is a positive real number, and the first distance d₁ is a positive real number; (b) in response to the current waypoint being not the final waypoint and the distance d_{wp} between the unmanned surface vehicle 200 and the current waypoint being less than or equal to a second distance d₂, calculating a difference d₂−d_{wp} between the second distance d₂ and a distance between the unmanned surface vehicle 200 and the current waypoint, and setting the completion reward value r_{comp} to a tenth numerical value a₁₀ multiplied by the aforementioned difference d₂−d_{wp}, where the tenth numerical value a₁₀ is a positive real number, and the second distance d₂ is a positive real number greater than the first distance d₁; and (c) in response to the current waypoint being not the final waypoint and the distance d_{wp} between the unmanned surface vehicle 200 and the current waypoint is greater than the second distance d₂, setting the completion reward value to 0. The completion reward value r_{comp} may be expressed by the following equation:

$${r}_{comp} = \{ \begin{matrix}{a}_{9} , if it is the final waypoint and {d}_{wp} \leq {d}_{1} , \\ {a}_{10} \cdot ( {d}_{2} - {d}_{wp} ) , if {d}_{wp} < {d}_{2} , \\ 0 , if it is the final waypoint and {d}_{wp} > {d}_{2}\end{matrix} .$$

where a₉>a₁₀. In some embodiments of the present invention, a₉=200, a_{10·}=10, d₁=0.5, and d₂=1.0.

It is worth noting that in the aforementioned embodiments, various objectives can be balanced by different weights, thereby ensuring that a target policy network trained via a twin delayed deep deterministic policy gradient algorithm can advance steadily and complete a mission while maintaining the path accuracy, and thus avoiding local optima (such as wandering in place or regressing).

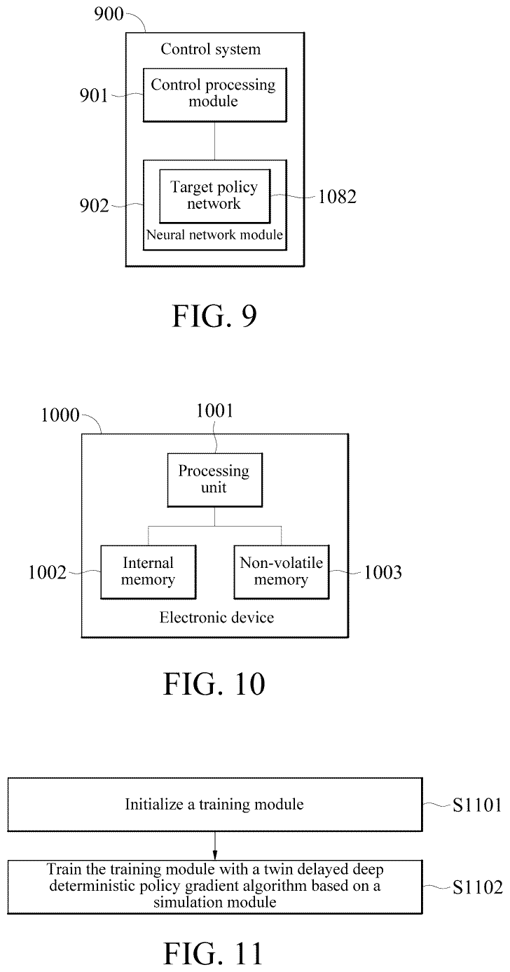

FIG. 9 is a block diagram of a control system illustrated according to some embodiments of the present invention. Referring to FIG. 9, a control system 900 includes a control processing module 901 and a neural network module 902. The neural network module 902 includes a trained target policy network 1082. The trained target policy network 1082 has a trained parameter \hat{φ}. After the training system 100 completes the training of the training module 104, the training system 100 transmits the trained target policy network 1082 to the control system 900 so as to make the neural network module 902 of the control system 900 store the trained target policy network 1082.

The control method of some embodiments of the present invention and how various modules of the control system 900 cooperate with each other will be described below in detail with the figures.

FIG. 16 is a flowchart of a control method illustrated according to some embodiments of the present invention. Referring to both FIG. 2, and FIG. 16, in an embodiment illustrated in FIG. 16, the control method includes performing steps S1601 to S1603 by the control processing module 901. In step S1601, the control processing module 901 receives a current surge velocity u_{current}, a current sway velocity v_{current}, a current position (x_{current}, y_{current}), a current heading angle Ψ_{u,current}, a current cross-track error y_{e,current}, and a current heading error Ψ_{err,current} of the unmanned surface vehicle 200 as a current state S_{current} of the unmanned surface vehicle 200. In step S1602, the control processing module 901 inputs the current state S_{current} to the trained target policy network 1082 so as to obtain an output. The trained target policy network 1082 is included in the neural network module 902. In step S1603, the control processing module 901 controls a propeller speed of a propeller of the unmanned surface vehicle 200 based on the output of the aforementioned target policy network 1082.

In some embodiments of the present invention, the control processing module 901 converts an output of the target policy network 1082 into a propeller speed of a propeller of the unmanned surface vehicle 200 based on a preset conversion relationship.

FIG. 10 is a block schematic diagram of an electronic device system illustrated according to some embodiments of the present invention. As shown in FIG. 10, at a hardware level, an electronic device 1000 includes a processing unit 1001, an internal memory 1002, and a non-volatile memory 1003. The internal memory 1002 is, for example, a random-access memory (RAM). The non-volatile memory 1003 is, for example, at least one magnetic disc memory. Certainly, the electronic device 1000 may further include hardware required for other functions.

The internal memory 1002 and the non-volatile memory 1003 are configured to store a program which may include program code including a computer operating instruction. The internal memory 1002 and the non-volatile memory 1003 provide instructions and data to the processing unit 1001. The processing unit 1001 reads a corresponding computer program from the non-volatile memory 1003 into the internal memory 1002 and then runs the computer program, thereby forming the training system 100 or the control system 900 at a logic level.

The processing unit 1001 may be an integrated circuit chip, which has signal processing capacity. In an implementation process, various methods and steps disclosed in the aforementioned embodiments may be implemented by an integrated logic circuit of hardware in the processing unit 1001 or an instruction in a software form. The processing unit 1001 may be a graphics processor or a general-purpose processor, including a central processing unit, a digital signal processor, an application specific integrated circuit, a field-programmable gate array, or other programmable logic devices. The processing unit can implement or perform the methods and steps disclosed in the aforementioned embodiments.

An embodiment of this description further provides a computer-readable storage medium storing at least one instruction which, when executed by the processing unit 1001 of the electronic device 1000, enables the processing unit 1001 of the electronic device 1000 to perform the various methods and steps disclosed in the aforementioned embodiments.

Examples of storage media for computers include, but are not limited to, a phase change random-access memory (PRAM), a static random-access memory (SRAM), a dynamic random-access memory (DRAM), other types of random-access memories (RAM), a read-only memory (ROM), an electrically erasable programmable read-only memory (EEPROM), a flash memory or other internal memory technologies, a compact disc read-only memory (CD-ROM), a digital versatile disc (DVD) or other optical storages, a magnetic cassette tape, a magnetic tape disk storage or other magnetic storage devices, or any other non-transmission media, which can be used for storing information that can be accessed by a computing device. As defined herein, computer-readable media do not include transitory media, such as modulated data signals and carriers.

Based on the above, some embodiments of the present invention provide a training system, a training method, a control system, and a control method, where in the design of reward functions, related factors such as a cross-track error, a heading error, progress, and completion are comprehensively considered. The cross-track error reward value gives a reward when an absolute value of a cross-track error is small and gives a penalty when the absolute value increases to ensure close adherence to a preset path. The cross-track error reward value may increase path accuracy. The heading error reward value is used for giving a reward when an absolute value of a heading error is small and giving a penalty when the absolute value increases to ensure correct orientation. The heading error reward value may increase heading accuracy. The progress reward value gives a reward when the unmanned surface vehicle advances in a mission direction and gives a penalty when the unmanned surface vehicle regresses or makes no progress to avoid wandering. The progress reward value may restrain a behavior, and penalize a negative velocity to prevent regressing. The completion reward value gives a reward when the unmanned surface vehicle approaches a waypoint and gives a greater reward when the unmanned surface vehicle reaches a final destination, thereby encouraging the completion of a whole path. In the overall design, a hierarchical reward structure is employed to balance all objectives, thereby ensuring that an agent advances steadily and completes a mission while maintaining the path accuracy, and thus avoiding local optima (such as wandering in place or regressing). In addition, by using the twin delayed deep deterministic policy gradient algorithm, the overestimation problem can be reduced, so that the trained target policy network, when practically applied to control, has better performance than a controller trained by other algorithms.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A training system, comprising:
a simulation unit, configured to, in response to receiving an action, return a reward corresponding to the action and a next state of a simulated unmanned surface vehicle, wherein the reward is the sum of a cross-track error reward value, a heading error reward value, a progress reward value, and a completion reward value, wherein the cross-track error reward value is used for giving a reward when an absolute value of a cross-track error is small and giving a penalty when the absolute value of the cross-track error increases, the heading error reward value is used for giving a reward when an absolute value of a heading error is small and giving a penalty when the absolute value of the heading error increases, the progress reward value is used for giving a reward when the unmanned surface vehicle advances in a mission direction and giving a penalty when the unmanned surface vehicle regresses or makes no progress, and the completion reward value is used for giving a reward when the unmanned surface vehicle approaches a current waypoint and reaches a final destination; and
a training unit, comprising a training module comprising an experience playback buffer, a first value network, a second value network, a policy network, a first target value network, a second target value network, and a target policy network, wherein the first target value network, the second target value network, and the target policy network are the same as the first value network, the second value network, and the policy network in architecture, respectively; and a processing module, configured to initialize the training module, and train the training module with a twin delayed deep deterministic policy gradient algorithm based on the simulation unit.

2. The training system according to claim 1, wherein the policy network is a first fully connected network, the first value network is a second fully connected network, the second value network is a third fully connected network, an activation function of an output layer of the first fully connected network is a hyperbolic tangent function, an activation function of an output layer of the second fully connected network is a linear function, and an activation function of an output layer of the third fully connected network is a linear function.

3. The training system according to claim 1, wherein the simulation unit generates the cross-track error reward value based on the following steps:
(a) in response to the absolute value of the cross-track error being less than or equal to a first predetermined value, setting the cross-track error reward value to a difference between the first predetermined value and the absolute value of the cross-track error multiplied by a first numerical value, wherein the first numerical value is a positive real number;
(b) in response to the absolute value of the cross-track error being greater than the first predetermined value and less than or equal to a second predetermined value, setting the cross-track error reward value to a difference between the absolute value of the cross-track error and the first predetermined value multiplied by a second numerical value, wherein the second numerical value is a negative real number; and
(c) in response to the absolute value of the cross-track error being greater than the second predetermined value, setting the cross-track error reward value to a third numerical value, wherein the third numerical value is a negative real number.

4. The training system according to claim 1, wherein the simulation unit generates the heading error reward value based on the following steps:
(a) in response to the absolute value of the heading error being less than or equal to a preset angle, calculating a ratio of the absolute value of the heading error to the preset angle, and setting the heading error reward value to a difference between 1 and the ratio multiplied by a fourth numerical value, wherein the preset angle is a positive angle and the fourth numerical value is a positive real number; and
(b) in response to the absolute value of the heading error being greater than the preset angle, setting the heading error reward value to a fifth numerical value multiplied by the absolute value of the heading error, wherein the fifth numerical value is a negative real number.

5. The training system according to claim 1, wherein the simulation unit generates the progress reward value based on the following steps:
(a) in response to a time-step movement increment being greater than a first variation amount, setting the progress reward value to a sixth numerical value multiplied by the time-step movement increment, wherein the first variation amount is a positive real number and the sixth numerical value is a positive real number;
(b) in response to the time-step movement increment being less than a second variation amount, setting the progress reward value to a seventh numerical value, wherein the second variation amount is a negative real number, and the seventh numerical value is a negative real number; and
(c) in response to the time-step movement increment being greater than or equal to the second variation amount and less than or equal to the first variation amount, setting the progress reward value to an eighth numerical value, wherein the eighth numerical value is a negative real number.

6. The training system according to claim 1, wherein the simulation unit generates the completion reward value based on the following steps:
(a) in response to the current waypoint being a final waypoint and a distance between the unmanned surface vehicle and the current waypoint being less than or equal to a first distance, setting the completion reward value to a ninth numerical value, wherein the ninth numerical value is a positive real number, and the first distance is a positive real number;
(b) in response to the current waypoint being not the final waypoint and the distance between the unmanned surface vehicle and the current waypoint being less than or equal to a second distance, calculating a difference between the second distance and the distance between the unmanned surface vehicle and the current waypoint, and setting the completion reward value to a tenth numerical value multiplied by the difference, wherein the tenth numerical value is a positive real number, and the second distance is a positive real number greater than the first distance; and
(c) in response to the current waypoint being not the final waypoint and the distance between the unmanned surface vehicle and the current waypoint being greater than the second distance, setting the completion reward value to 0.

7. A control system for a trained target policy network obtained by training using the training system according to claim 1, the control system comprising:
a neural network module, comprising the trained target policy network; and
a control processing module, configured to perform: receiving a current surge velocity, a current position, a current heading angle, a current cross-track error, and a current heading error of an unmanned surface vehicle as a current state of the unmanned surface vehicle, wherein the current heading error is a difference between an ideal heading angle generated by an adaptive line-of-sight guidance law and a current heading angle of the unmanned surface vehicle; inputting the current state into the trained target policy network to obtain an output; and controlling a propeller speed of the unmanned surface vehicle based on the output.

8. A training method, applicable to a training system, wherein the training system comprises a simulation unit, configured to, in response to receiving an action, return a reward corresponding to the action and a next state of a simulated unmanned surface vehicle, wherein the reward is the sum of a cross-track error reward value, a heading error reward value, a progress reward value, and a completion reward value, wherein the cross-track error reward value is used for giving a reward when an absolute value of a cross-track error is small and giving a penalty when the absolute value of the cross-track error increases, the heading error reward value is used for giving a reward when an absolute value of a heading error is small and giving a penalty when the absolute value of the heading error increases, the progress reward value is used for giving a reward when the unmanned surface vehicle advances in a mission direction and giving a penalty when the unmanned surface vehicle regresses or makes no progress, and the completion reward value is used for giving a reward when the unmanned surface vehicle approaches a current waypoint and reaches a final destination; and a training unit, comprising a training module comprising an experience playback buffer, a first value network, a second value network, a policy network, a first target value network, a second target value network, and a target policy network, wherein the first target value network, the second target value network, and the target policy network are the same as the first value network, the second value network, and the policy network in architecture, respectively; and a processing module; the training method comprises, by the processing module, performing:
(a) initializing the training module; and
(b) training the training module with a twin delayed deep deterministic policy gradient algorithm based on the simulation unit.

9. The training method according to claim 8, wherein the policy network is a first fully connected network, the first value network is a second fully connected network, the second value network is a third fully connected network, an activation function of an output layer of the first fully connected network is a hyperbolic tangent function, an activation function of an output layer of the second fully connected network is a linear function, and an activation function of an output layer of the third fully connected network is a linear function.

10. The training method according to claim 8, wherein the simulation unit generates the cross-track error reward value based on the following steps:
(a) in response to the absolute value of the cross-track error being less than or equal to a first predetermined value, setting the cross-track error reward value to a difference between the first predetermined value and the absolute value of the cross-track error multiplied by a first numerical value, wherein the first numerical value is a positive real number;
(b) in response to the absolute value of the cross-track error being greater than the first predetermined value and less than or equal to a second predetermined value, setting the cross-track error reward value to a difference between the absolute value of the cross-track error and the first predetermined value multiplied by a second numerical value, wherein the second numerical value is a negative real number; and
(c) in response to the absolute value of the cross-track error being greater than the second predetermined value, setting the cross-track error reward value to a third numerical value, wherein the third numerical value is a negative real number.

11. The training method according to claim 8, wherein the simulation unit generates the heading error reward value based on the following steps:
(a) in response to the absolute value of the heading error being less than or equal to a preset angle, calculating a ratio of the absolute value of the heading error to the preset angle, and setting the heading error reward value to a difference between 1 and the ratio multiplied by a fourth numerical value, wherein the preset angle is a positive angle and the fourth numerical value is a positive real number; and
(b) in response to the absolute value of the heading error being greater than the preset angle, setting the heading error reward value to a fifth numerical value multiplied by the absolute value of the heading error, wherein the fifth numerical value is a negative real number.

12. The training method according to claim 8, wherein the simulation unit generates the progress reward value based on the following steps:
(a) in response to a time-step movement increment being greater than a first variation amount, setting the progress reward value to a sixth numerical value multiplied by the time-step movement increment, wherein the first variation amount is a positive real number and the sixth numerical value is a positive real number;
(b) in response to the time-step movement increment being less than a second variation amount, setting the progress reward value to a seventh numerical value, wherein the second variation amount is a negative real number, and the seventh numerical value is a negative real number; and
(c) in response to the time-step movement increment being greater than or equal to the second variation amount and less than or equal to the first variation amount, setting the progress reward value to an eighth numerical value, wherein the eighth numerical value is a negative real number.

13. The training method according to claim 8, wherein the simulation unit generates the completion reward value based on the following steps:
(a) in response to the current waypoint being a final waypoint and a distance between the unmanned surface vehicle and the current waypoint being less than or equal to a first distance, setting the completion reward value to a ninth numerical value, wherein the ninth numerical value is a positive real number, and the first distance is a positive real number;
(b) in response to the current waypoint being not the final waypoint and the distance between the unmanned surface vehicle and the current waypoint being less than or equal to a second distance, calculating a difference between the second distance and the distance between the unmanned surface vehicle and the current waypoint, and setting the completion reward value to a tenth numerical value multiplied by the difference, wherein the tenth numerical value is a positive real number, and the second distance is a positive real number greater than the first distance; and
(c) in response to the current waypoint being not the final waypoint and the distance between the unmanned surface vehicle and the current waypoint being greater than the second distance, setting the completion reward value to 0.

14. A control system for a trained target policy network obtained by training using the training method according to claim 8, wherein the control method is performed by a control processing module, and the control method comprises:
(a) receiving a current surge velocity, a current position, a current heading angle, a current cross-track error, and a current heading error of an unmanned surface vehicle as a current state of the unmanned surface vehicle, wherein the current heading error is a difference between an ideal heading angle generated by an adaptive line-of-sight guidance law and a current heading angle of the unmanned surface vehicle;
(b) inputting the current state into the trained target policy network to obtain an output, wherein the trained target policy network is comprised in a neural network module; and
(c) controlling a propeller speed of the unmanned surface vehicle based on the output.
